(19) United States
(12) Patent Application Publication
(10) Pub. No.: US 2026/0096026 A1
(43) Pub. Date: Apr. 2, 2026

(54) IMAGE CAPTURING APPARATUS

(71) Applicant: CANON KABUSHIKI KAISHA, Tokyo (JP)

(72) Inventors: RYOTA GOMI, Tokyo (JP); HIDETA NISHIZAWA, Tokyo (JP); YASUHIKO SANO, Kanagawa (JP)

(21) Appl. No.: 19/329,778

(22) Filed: Sep. 16, 2025

(30) Foreign Application Priority Data
Oct. 1, 2024 (JP) 2024-172635

(51) Int. Cl. H05K 1/14; H04N 25/709; H10F 39/00

(52) U.S. Cl. CPC H05K 1/148; H04N 25/709; H10F 39/811; H05K 2201/10151

(57) ABSTRACT

An image capturing apparatus includes a main substrate on which a power supply unit is arranged, an image sensor, an imaging substrate mounted with the image sensor, a flexible substrate that is connected to the main substrate and the imaging substrate, and a step-down switching power supply that is mounted on a surface different from a surface on which the image sensor is mounted on the imaging substrate, wherein the step-down switching power supply includes an integrated circuit, a first capacitor connected to a power supply input side of the integrated circuit, an inductor connected to an output terminal of the integrated circuit, and a second capacitor connected to a terminal, and the inductor and the second capacitor are arranged outside a region where the image sensor is projected onto the imaging substrate.

### BACKGROUND

### Field of the Technology

The present disclosure relates to a power supply technique to an image sensor in an image capturing apparatus.

### Description of the Related Art

In an image capturing apparatus such as a known single lens reflex camera or a mirrorless camera, due to concern of image quality degradation due to a magnetic field, a power supply of an image sensor is arranged on another substrate away from an imaging substrate mounted with the image sensor. Power is supplied to the imaging substrate via a flexible substrate (flexible printed circuit) from the power supply arranged on the other substrate.

In recent years, in order to realize an image blur correction function by moving the image sensor, the imaging substrate is generally configured to be physically moved. Therefore, it is desirable that the flexible substrate is provided with a long extra length, the wiring width is made as thin as possible, and the thickness is also made thin so as not to hinder movement of the imaging substrate.

On the other hand, in recent years, the consumption current of the image sensor has increased with an increase in the readout rate of the image sensor and an increase in the number of pixels. Accordingly, the current flowing through the flexible substrate tends to increase. The increase in the current flowing through the flexible substrate causes problems such as image quality degradation due to an increase in the magnetic field strength generated from the flexible substrate. The current increases, and an increase in a heat generation amount due to wiring resistance or the like also leads to image quality degradation.

As a method of supplying power to the image sensor, Japanese Patent Laid-Open No. 2022-172947 discloses a method of suppressing a current in a first power supply circuit unit by providing a second power supply circuit unit in addition to the first power supply circuit unit.

However, the known technique disclosed in Japanese Patent Laid-Open No. 2022-172947 cannot reduce the total amount of current flowing through the flexible substrate.

The known technique disclosed in Japanese Patent Laid-Open No. 2022-172947 raises a concern that the image quality is degraded by the magnetic field from the second power supply circuit unit in a case where the second power supply circuit unit is arranged close to the image sensor.

### SUMMARY

The present disclosure has been made in view of the above-described problems, and provides an image capturing apparatus that can suppress image quality degradation while reducing the total amount of current flowing through a flexible substrate.

According an aspect of the present disclosure, there is provided an image capturing apparatus comprising: a main substrate on which a power supply unit is arranged; an image sensor including a pixel unit in which a plurality of pixels are two-dimensionally arranged, and a circuit unit that reads a signal of the pixels; an imaging substrate mounted with the image sensor; a flexible substrate that is connected to the main substrate and the imaging substrate and supplies power from the power supply unit to the imaging substrate; and a step-down switching power supply that is mounted on a surface different from a surface on which the image sensor is mounted on the imaging substrate, steps down a voltage supplied via the flexible substrate, and supplies power to the image sensor, wherein the step-down switching power supply includes an integrated circuit in which a switching element and a control circuit are integrated, a first capacitor connected to a power supply input side of the integrated circuit, an inductor connected to an output terminal of the integrated circuit, and a second capacitor connected to a terminal different from a terminal connected to an output terminal of the integrated circuit of the inductor, and the inductor and the second capacitor are arranged, on the imaging substrate, outside a region where the image sensor is projected onto the imaging substrate.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a block diagram illustrating a configuration for supplying power to an image sensor in an image capturing apparatus of a first embodiment.

FIG. 2 is a view illustrating a schematic configuration of the image sensor included in the image capturing apparatus.

FIG. 3 is a view explaining signal processing of the image sensor.

FIG. 4 is a view illustrating a configuration of a step-down switching power supply.

FIG. 5 is a conceptual view illustrating a relationship between a readout frequency of the image sensor and a switching frequency of the step-down switching power supply.

FIG. 6 is a layout diagram of the step-down switching power supply of the imaging substrate in the first embodiment.

FIG. 7 is a layout diagram of a step-down switching power supply of an imaging substrate in a second embodiment.

FIG. 8 is a cross-sectional view of an image capturing unit in a third embodiment.

FIG. 9 is a first layout diagram of a conductor of an imaging substrate in a fourth embodiment.

FIG. 10 is a second layout diagram of the conductor of the imaging substrate in the fourth embodiment.

FIG. 11 is a layout diagram of a step-down switching power supply of an imaging substrate in a fifth embodiment.

FIG. 12 is a layout diagram of an inductor of an imaging substrate in a sixth embodiment.

FIG. 13 is a view illustrating a schematic configuration of an image sensor of a stacked type in a seventh embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

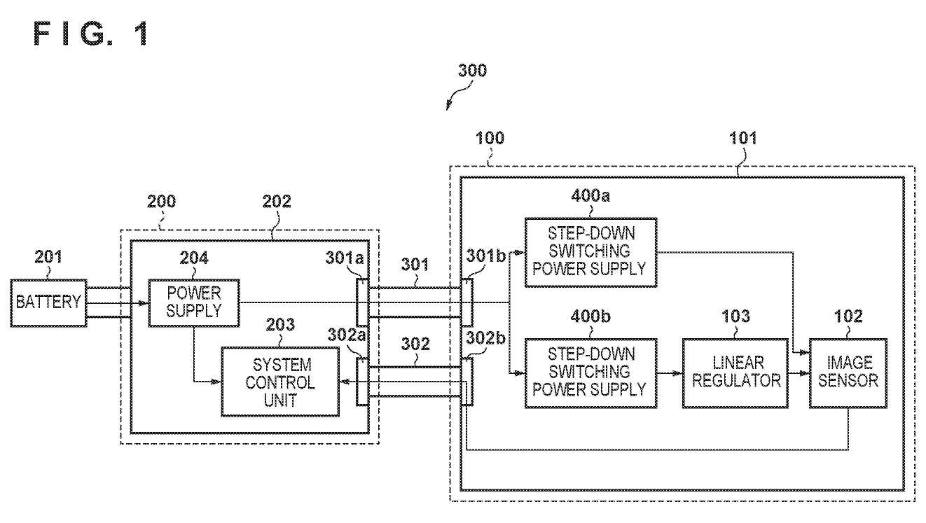

FIG. 1 is a block diagram illustrating the configuration for supplying power to the image sensor in the image capturing apparatus of the first embodiment of the present invention.

In FIG. 1, an image capturing apparatus 300 is configured to include an image capturing unit 100, a main substrate unit (main PCB unit) 200, flexible substrates (FPC) 301 and 302 that connect these units, and a battery 201.

The battery 201 corresponds to a power supply of the image capturing apparatus 300, and is, for example, a lithium ion battery that can be easily detached from and attached to the image capturing apparatus 300.

The main substrate unit 200 is configured to include a main substrate (main PCB) 202, a system control unit 203, a power supply 204, connectors 301a and 302a, and other resistors and capacitors not illustrated.

The main substrate 202 is a printed circuit board (PCB) mounted with the system control unit 203 and a power supply circuit such as the power supply 204.

The system control unit 203 controls the entire image capturing apparatus including the image capturing unit 100, and acquires an image signal from the image capturing unit 100 via the flexible substrate 302.

The power supply (power supply unit) 204 is arranged on the main substrate 202, and includes one or a plurality of power supply circuits that convert a voltage supplied from the battery 201 into a voltage required by each of the system control unit 203 and the image capturing unit 100 to output it. Supply of power from the power supply 204 to the image capturing unit 100 is performed from the main substrate 202 via the connector 301a and the flexible substrate 301. Note that a configuration in which power is directly supplied from the battery 201 to the image capturing unit 100 may be adopted. The flexible substrate 301 is connected to the image capturing unit 100 via the connector 301b.

The image capturing unit 100 is configured to include an imaging substrate (imaging PCB) 101, an image sensor 102, a linear regulator 103, step-down switching power supplies 400a and 400b, connectors 301b and 302b, and other resistors and capacitors not illustrated.

The imaging substrate 101 is a printed circuit board (PCB) having a power supply wiring formed of metal such as copper. For the imaging substrate 101, a rigid substrate is used to equip the image sensor 102, and is formed of, for example, glass epoxy or the like. However, the imaging substrate 101 is not limited to this, and the imaging substrate 101 may be a flexible substrate using a plastic material or a low temperature co-fired ceramics (LTCC) substrate using ceramics and copper wiring. That is, any substrate may be used as long as a metal wiring pattern such as copper is formed on a specific material, and components can be equipped (mounted).

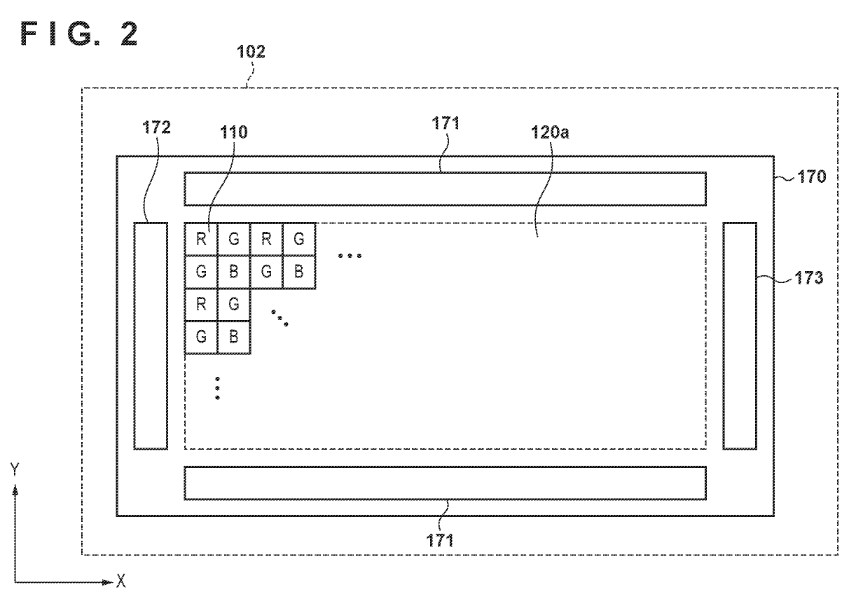

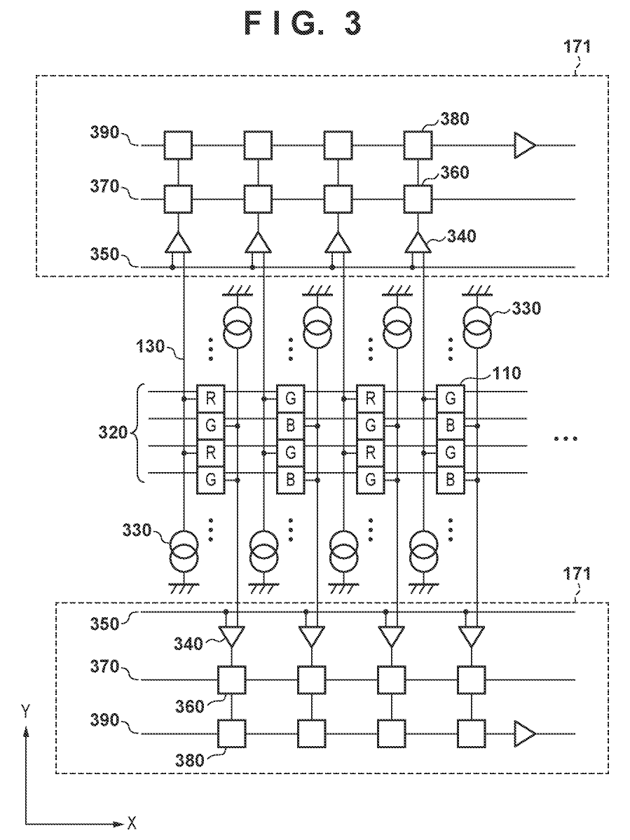

The image sensor 102 includes a CMOS image sensor that outputs an image signal in response to incident light. More specifically, as described later with reference to FIGS. 2 and 3, the image sensor 102 is a CMOS image sensor of an XY address type, performs an imaging operation in accordance with a control signal from the system control unit 203, and outputs an image signal. The image signal is transmitted from the image capturing unit 100 to the main substrate 202 via the connector 302b, the flexible substrate 302, and the connector 302a, and is input to the system control unit 203.

The step-down switching power supplies 400a and 400b are arranged on the imaging substrate 101. The step-down switching power supply 400a is a power supply circuit that steps down the voltage supplied from the power supply 204 to a first power supply voltage required by the image sensor 102. The step-down switching power supply 400b is a power supply circuit that generates a voltage to be input to the linear regulator 103.

Note that although FIG. 1 illustrates an example in which the imaging substrate 101 includes two step-down switching power supplies, the imaging substrate 101 may include one or three or more step-down switching power supplies. Hereinafter, the step-down switching power supplies 400a and 400b are described as the step-down switching power supply 400 when collectively written.

The linear regulator 103 is a linear regulator that steps down the output voltage of the step-down switching power supply 400b to a second power supply voltage required by the image sensor 102.

As described above, by arranging the step-down switching power supply 400 onto the imaging substrate 101, the main substrate 202 supplies power to the imaging substrate 101 at a predetermined voltage higher than a voltage required for the image sensor 102 to operate (operating voltage of the image sensor 102). A predetermined voltage higher than the operating voltage of the image sensor 102 is supplied to the imaging substrate 101 via the flexible substrate 301. Therefore, the amount of current flowing through the flexible substrate 301 can be reduced, and the strength of the magnetic field generated by the current flowing through the flexible substrate 301 can be made small. As a result, it is possible to reduce degradation in image quality of the image signal from the image sensor 102 due to the magnetic field generated by the flexible substrate 301. For example, by setting a predetermined voltage supplied by the power supply unit 204 to a voltage N times the operating voltage of the image sensor 102, a voltage of 1/N of the predetermined voltage is supplied to the image sensor 102 by the step-down switching power supply 400. The voltage is stepped down to 1/N of the predetermined voltage by the step-down switching power supply 400, whereby the current to be output from the step-down switching power supply 400 becomes N times the current output from the power supply unit 204 and flowing through the flexible substrate 301. Due to the step-down switching power supply 400 being equipped on the imaging substrate 101, the step-down switching power supply 400 is arranged close to the image sensor 102. A method of reducing image quality degradation due to the magnetic field generated by the step-down switching power supply 400 in that case will be described below.

FIG. 2 is a view illustrating a schematic configuration of the image sensor 102 included in the image capturing apparatus.

The image sensor 102 is a CMOS sensor including a pixel unit 120a configured to include a plurality of pixels 110, and a circuit unit 170 configured to include a signal processing unit 171, a control unit 172, and an output unit 173. The pixel unit 120a is configured to include the plurality of pixels 110 arrayed in a matrix (two-dimensional) in a horizontal direction (X direction) and a vertical direction (Y direction) orthogonal to each other. In the pixel unit 120a, color filters in a 2 × 2 array in which odd-numbered rows are configured by repetition of a red (R) filter and a green (G) filter and even-numbered rows are configured by repetition of the green (G) filter and a blue (B) filter are arranged so as to correspond to each of the pixels 110.

The signal processing unit 171 is a circuit that performs signal processing such as A/D conversion on the image signal in units of rows sent via a vertical output line 130 (see FIG. 3). The control unit 172 is a circuit that selects the pixel array of the pixel unit 120a row by row and controls the reset operation and the readout operation of the selected pixel row. The output unit 173 is a circuit that outputs an image signal in units of rows having been digitized to the outside of the image sensor 102.

FIG. 3 is a view explaining signal processing of the image sensor 102.

The vertical output line 130 is arranged in the column direction of the pixels, and is commonly connected to the pixels of each row for each pixel column. The image signals of the rows selected by pixel control lines 320 are read out to the corresponding vertical output lines 130. The pixel control line 320 simultaneously controls the pixels 110 in one horizontal row, and enables reset and signal readout. A load current source 330 drives the pixels 110 of the selected row via the vertical output line 130.

An analog signal of the pixel 110 is input to one input terminal of a comparator 340. A reference signal line 350 is connected to the other input terminal of the comparator 340, and a reference signal output from a reference signal generator not illustrated is input through the reference signal line 350. An output terminal of the comparator 340 is connected to a latch circuit 360. The latch circuit 360 holds a count value of a counter not illustrated input from a signal line 370 at a timing when the magnitudes of the analog signal of the pixel and the reference signal are reversed and the output of the comparator 340 is changed. The held count value is stored in a memory 380 and held as a digital value. The digital signal stored in the memory 380 is transferred to the subsequent stage of the signal processing unit 171 via a horizontal transfer line 390, and various types of processing such as offset processing and gain processing are performed. The digital signal having passed through the signal processing unit 171 is output from the output unit 173 to the outside through an interface (I/F). This I/F is, for example, SubLVDS, SLVS, SLVS-EC, or the like.

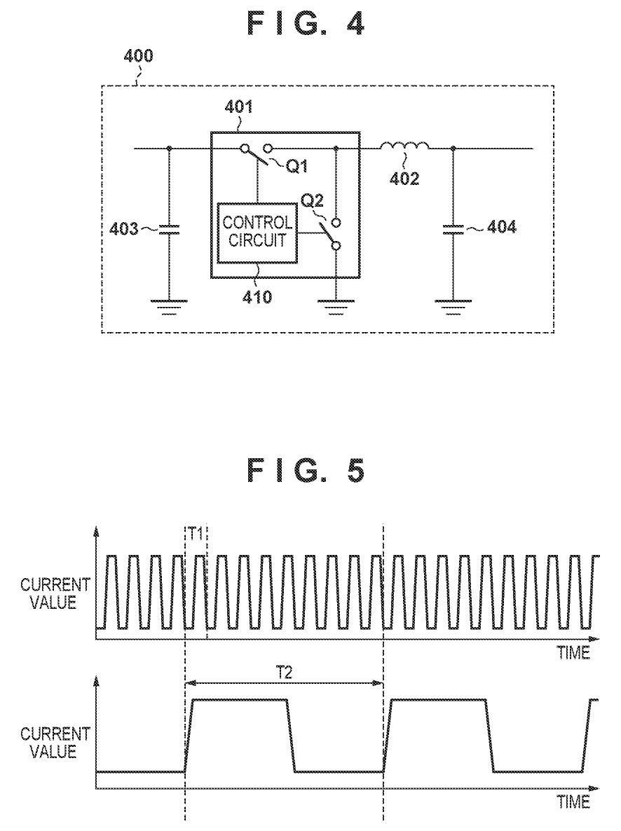

FIG. 4 is a view illustrating the configuration of step-down switching power supply 400. The step-down switching power supply 400 includes an integrated circuit 401 in which switching elements Q1 and Q2 and a control circuit 410 are integrated, and a first capacitor 403 connected to a power supply input side of the integrated circuit 401. The step-down switching power supply 400 further includes an inductor 402 connected to an output terminal of the integrated circuit 401, and a second capacitor 404 connected to a terminal different from the terminal connected to the output terminal of the integrated circuit 401 of the inductor 402. Note that the number of each of the inductor 402, the first capacitor 403, and the second capacitor 404 is not limited to one, and a plurality of them may be arranged.

The control circuit 410 is a control circuit that controls the switching elements Q1 and Q2 so that the output voltage of the step-down switching power supply 400 has a desired value. The switching elements Q1 and Q2 are, for example, FETs, and are switching elements constituting the step-down switching power supply 400.

Switching control of the step-down switching power supply 400 mainly includes two types of pulse width modulation (PWM) fixed control and pulse frequency modulation (PFM) control. While the PWM fixed control operates with the switching frequency fixed, in a PFM operation mode, the switching frequency is varied depending on the load. The present embodiment may use either switching control.

As the switching drive is performed at a higher frequency, a capacitor or an inductor having a smaller size can be selected, and the device can be more downsized. However, the higher the frequency is, the larger the switching loss, dead time loss, and the like become, and the lower the efficiency is. Therefore, the switching frequency of the step-down switching power supply is selected to balance the size and efficiency. The step-down switching power supply 400 performs switching at a higher frequency than the load variation (readout frequency) of the image sensor 102 in order to supply a stable power supply. For example, the step-down switching power supply 400 is configured to perform switching at a frequency of 1 to 3 MHz (1 MHz or more).

FIG. 5 is a conceptual view illustrating the relationship between the readout frequency of the image sensor 102 and the switching frequency of the step-down switching power supply 400. The vertical axis represents current, and the horizontal axis represents time.

The upper graph indicates that the current flowing through the first capacitor 403 varies at a switching frequency f1 by the switching drive of the step-down switching power supply 400. In the step-down switching power supply 400, the switching frequency f1 = 1/T1 where the time required for the switching element Q1 or Q2 to be on again after being on is T1.

The lower graph indicates that the current flowing through the inductor 402 and the second capacitor 404 varies at a readout frequency f2 by the readout operation of the image sensor 102 controlled by the control unit 172. In the image sensor 102, the readout frequency f2 = 1/T2 where a time until the image signal of one row is read out to the signal processing unit 171 via the vertical signal line 130, A/D conversion is performed, and the digital signal is output to the outside is T2. The frequency f1 is higher than the frequency f2.

A first magnetic field is generated from the first capacitor 403 and the wiring of the integrated circuit 401 due to the current variation accompanying the switching drive of the step-down switching power supply 400. On the other hand, by the readout of the image sensor 102, charging/discharging of the current occurs in the wiring from the inductor 402 and the second capacitor 404 to the image sensor 102, and a second magnetic field is generated by this current change. The first magnetic field has a higher frequency than the second magnetic field.

The step-down switching power supply 400 is arranged on the back surface of the imaging substrate 101 on which the image sensor 102 is arranged. Therefore, a path through which the magnetic field generated from the step-down switching power supply 400 reaches the image sensor 102 includes a path going around the end of the imaging substrate 101 and a path penetrating the imaging substrate 101. The longer the path going around the end of the imaging substrate 101 is, the more the magnetic field reaching the image sensor 102 attenuates, and therefore, the more the step-down switching power supply 400 is separated from the end of the imaging substrate 101, the more the magnetic field attenuates. In the path penetrating the imaging substrate 101, the magnetic field attenuates due to a skin effect by the conductor in the imaging substrate 101, and in particular, the higher the frequency is, the more the magnetic field is attenuated.

Therefore, since the first magnetic field generated by the first capacitor 403 is higher in frequency than the second magnetic field generated by the inductor 402 and the second capacitor 404, the magnetic field penetrating the imaging substrate 101 attenuates.

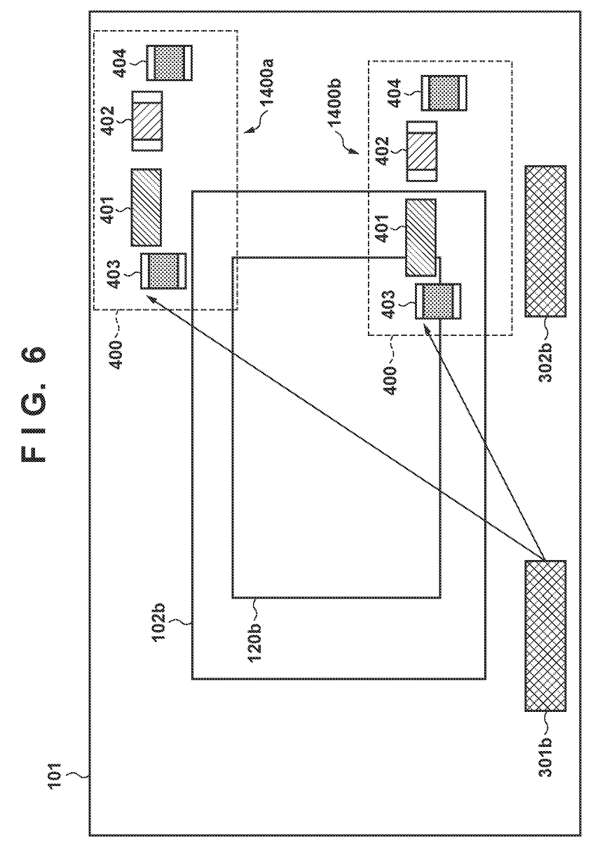

FIG. 6 is a view illustrating the arrangement of the step-down switching power supply 400 of the imaging substrate 101 in the first embodiment. FIG. 6 illustrates a case where the imaging substrate 101 is viewed from the surface on the side mounted with the image sensor 102. In FIG. 6, the step-down switching power supply 400 is indicated by a broken line, and the step-down switching power supply 400 is arranged on the back side of the surface of the imaging substrate 101 on which the image sensor 102 is arranged.

A pixel region 120b is a region in which a region where the pixel unit 120a of the image sensor 102 is arranged is projected onto the imaging substrate 101 (on the imaging substrate), and an image sensor region 102b is a region in which a region where the image sensor 102 is arranged is projected onto the imaging substrate 101 (on the imaging substrate). In order to avoid the magnetic field penetrating the imaging substrate 101 from reaching the pixel unit 120a, as indicated by a broken-line rectangle 1400a in FIG. 6, all elements that are the generation sources of the magnetic field of the step-down switching power supply 400 are arranged outside the image sensor region 102b. Alternatively, in a case where there is a restriction on the component arrangement region of the imaging substrate 101 and it is difficult to arrange all the elements serving as the generation source of the magnetic field outside the image sensor region 102b, they are arranged outside the pixel region 120b.

The following may be performed in consideration of the magnetic field attenuation due to the skin effect of the imaging substrate 101. That is, as indicated by a broken-line rectangle 1400b in FIG. 6, the inductor 402 that generates a relatively low-frequency magnetic field and the second capacitor 404 of the step-down switching power supply 400 are arranged outside the image sensor region 102b. Then, the first capacitor 403 that generates a relatively high-frequency magnetic field is arranged inside the image sensor region 102b.

Note that the arrangement of the step-down switching power supply 400 in the imaging substrate 101 described above is an example, and is not necessarily limited to this arrangement.

In the first embodiment, an example in which at least the inductor 402 and the second capacitor 404 included in the step-down switching power supply 400 are arranged outside the pixel region 120b or the image sensor region 102b has been described. In this manner, by arranging the step-down switching power supply 400 onto the imaging substrate 101, it is possible to reduce the amount of current flowing through the power supply path of the imaging substrate 101 and reduce degradation in image quality due to the magnetic field generated by the flexible substrate 301. Furthermore, by arranging the step-down switching power supply 400 onto the imaging substrate 101 in the arrangement described above, it is possible to reduce degradation in image quality due to the magnetic field generated by the step-down switching power supply 400.

### Second Embodiment

In the first embodiment, the configuration for reducing the influence of the magnetic field penetrating the imaging substrate 101 to reach the image sensor 102 has been described.

In the second embodiment of the present invention, a configuration for reducing the influence of the magnetic field that goes around the end of the imaging substrate 101 to reach the image sensor 102, of the magnetic field generated by the step-down switching power supply 400, will be described. Hereinafter, a magnetic field generated by the step-down switching power supply 400 and going around the end of the imaging substrate 101 to reach the image sensor 102 is called a go-around magnetic field from the switching power supply 400.

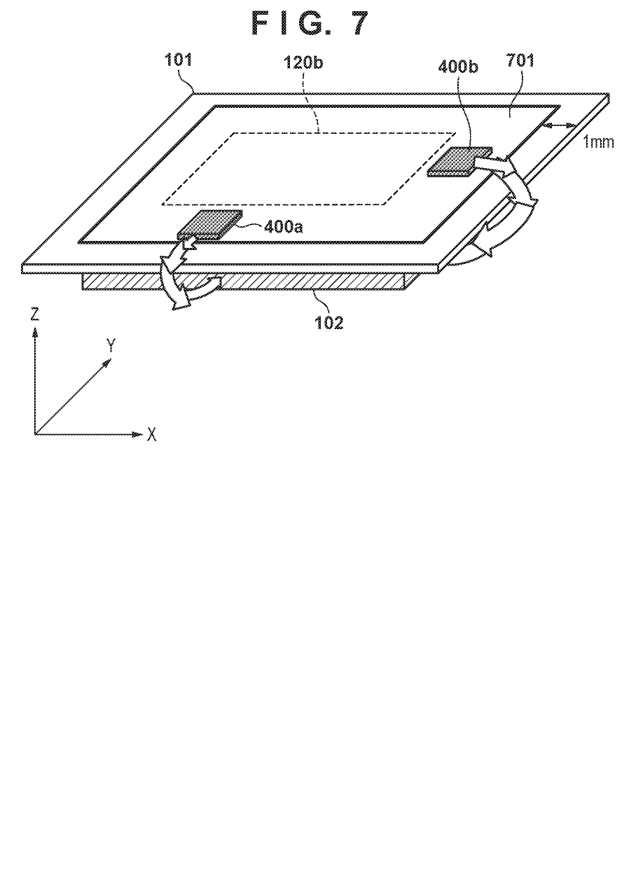

FIG. 7 is a view illustrating the arrangement of the step-down switching power supply 400 of the imaging substrate 101 in the second embodiment. The go-around magnetic field from the switching power supply 400 is a magnetic field that goes around the end of the imaging substrate 101 to reach the image sensor 102 on the back surface. According to Biot–Savart law, the magnetic field is inversely proportional to the square to cube of the distance. Therefore, the more the position where the step-down switching power supply 400 is arranged is separated from the substrate end of the imaging substrate 101, the more the go-around magnetic field from the step-down switching power supply 400 can be suppressed. In particular, the magnetic field suppression effect is high in a case where the step-down switching power supply 400 is arranged 1 to 2 mm away from the substrate end. Therefore, by arranging the step-down switching power supply 400 in a region 701 separated from the end of the imaging substrate 101 by 1 mm or more, it is possible to suppress the go-around magnetic field from the step-down switching power supply 400.

In the second embodiment, an example in which the step-down switching power supply 400 is arranged in the region 701 separated from the substrate end of the imaging substrate 101 by 1 mm or more has been described. The configuration of the second embodiment can reduce noise generated in an image signal due to the magnetic field generated from the step-down switching power supply 400 and going around the substrate end of the imaging substrate 101 to reach the image sensor 102.

### Third Embodiment

FIG. 8 is a cross-sectional view illustrating the configuration of the image capturing unit 100 in the third embodiment. The imaging substrate 101 has a multilayer structure (structure including a multilayer board). The imaging substrate 101 includes a wiring layer 150, an insulating layer 900, and a connection conductor 800 connecting the wiring layers 150.

The wiring layer 150 is a layer for providing a power supply line and a communication system wiring, and is made of a conductor such as copper. The insulating layer 900 made of prepreg is provided between the wiring layers 150. The connection conductor 800 is made of a conductor and has a role of electrically connecting the wiring layers 150. For example, it is constituted by a drill via.

Since the magnetic field attenuates by the skin effect of the conductor, the magnetic field generated by the power supply line wired in the wiring layer 150 attenuates by the wiring layers 150 until reaching the image sensor 102. Therefore, a power supply line through which a large current flows is arranged in a wiring layer far from the image sensor 102, and a power supply line and a communication system wiring through which a small current flows are arranged in a wiring layer close to the image sensor 102.

In the third embodiment, an example in which the power supply line through which a large current flows is wired away from the image sensor 102 has been described. With the configuration of the third embodiment, the magnetic field generated by the current flowing through the power supply wiring is attenuated by the skin effect, and noise of the image signal can be suppressed.

### Fourth Embodiment

In a fourth embodiment, a method of suppressing, using a conductor, a go-around magnetic field by a switching power supply will be described.

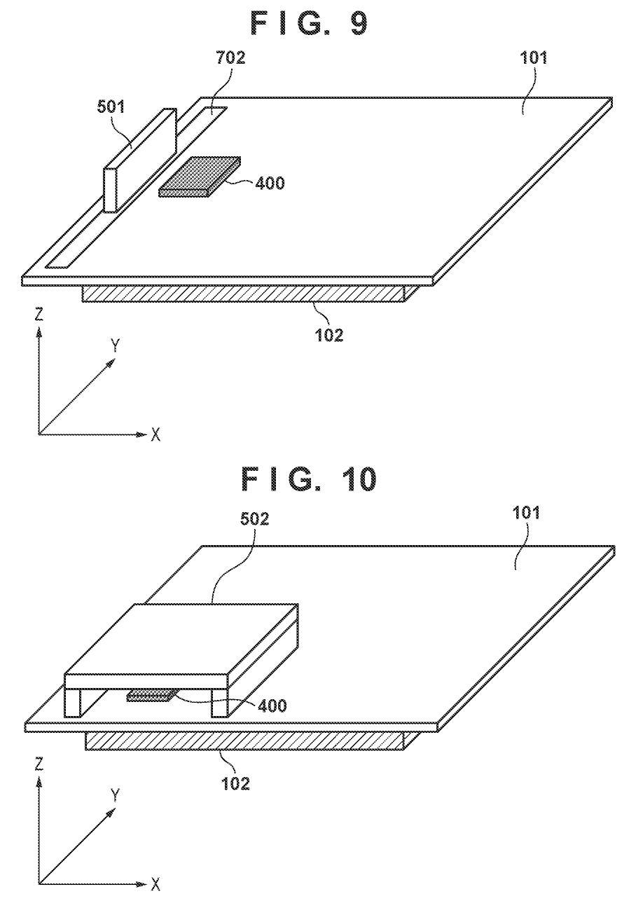

FIG. 9 is a first layout diagram of the conductor of the imaging substrate 101 in the fourth embodiment. Suppression of a penetrating magnetic field by the skin effect is performed by the conductor in the imaging substrate 101. Therefore, also in a case where a conductor 501 is arranged at an end portion of the imaging substrate 101, the go-around magnetic field by the switching power supply 400 can be similarly suppressed by the skin effect. Therefore, the conductor 501 is arranged in a substrate end region 702 in the vicinity of the step-down switching power supply 400. Note that a plurality of the conductors 501 may be arranged in the substrate end region 702.

FIG. 10 is a second layout diagram of the conductor of the imaging substrate 101 in the fourth embodiment. By covering the step-down switching power supply 400 with a conductor 502 from a Z direction, the magnetic field in the Z direction among the magnetic fields generated by the switching power supply 400 is suppressed by the skin effect of the conductor 502. In an electronic device including an image capturing apparatus, a copper wire in an inductor is often wound clockwise or anticlockwise when viewed from the Z direction, and a magnetic field is radiated in the Z direction by the right-hand screw rule. Therefore, by suppressing the magnetic field in the Z direction by the conductor 502, it is possible to suppress the go-around magnetic field by the switching power supply 400.

In the fourth embodiment, an example of arranging the conductors 501 and 502 on the imaging substrate 101 has been described. The configuration of the fourth embodiment can suppress the go-around magnetic field by the step-down switching power supply 400.

### Fifth Embodiment

In the fifth embodiment, the relationship between the orientation of the magnetic field and the image sensor 102 will be described. As illustrated in FIG. 3, signals of the plurality of pixels 110 are read out in the Y direction by the vertical signal line 130. Noise generated in the image signal is mainly generated by the magnetic field in the X direction interlinking with the vertical signal line 130.

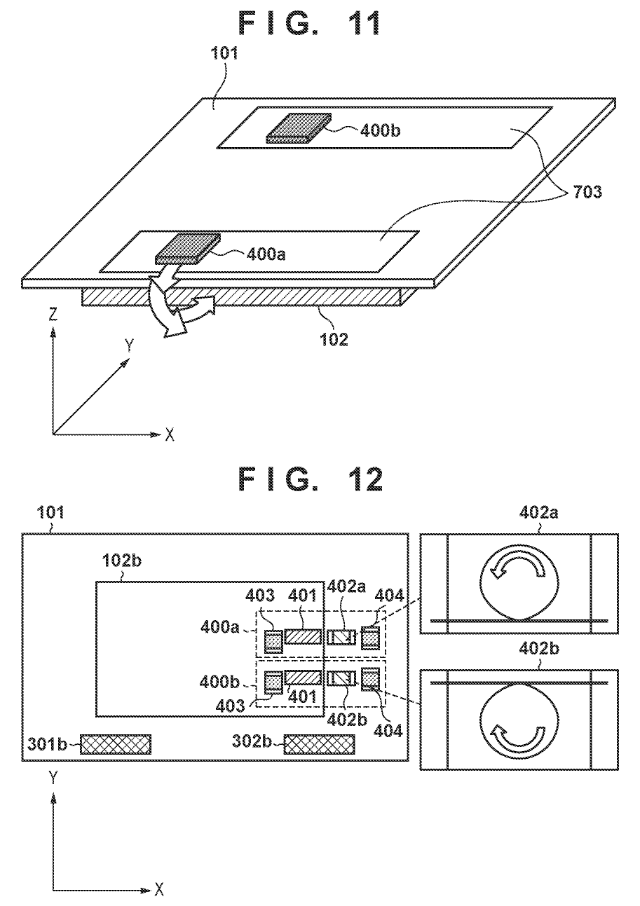

FIG. 11 is a layout diagram of the step-down switching power supply 400 of the imaging substrate 101 in the fifth embodiment. Among the magnetic fields generated by the switching power supply 400, the go-around magnetic field is mainly generated in the direction of the end portion of the imaging substrate 101 closest to the step-down switching power supply 400. In a case where the step-down switching power supply 400 is arranged at a position close to the end portion in the X direction of the imaging substrate 101, the go-around magnetic field in the X direction among the magnetic fields generated by the step-down switching power supply 400 interlinks with the vertical signal line 130. Therefore, noise is generated in the image signal obtained by the image sensor 102 due to the influence of the go-around magnetic field in this X direction. In a case where the step-down switching power supply 400 is arranged in a region 703 close to the end portion in the Y direction, the go-around magnetic field in the Y direction (indicated by an arrow in FIG. 11) among the magnetic fields generated by the step-down switching power supply 400 becomes parallel to the vertical signal line 130. Therefore, noise of the image signal obtained by the image sensor 102 is suppressed. Therefore, in the fifth embodiment, the step-down switching power supply 400 is arranged in the region 703 close to the end portion in the Y direction of the imaging substrate 101.

In the fifth embodiment, an example in which the step-down switching power supply 400 is arranged in the peripheral region 703 in the vertical direction (in the vicinity of the side in the direction intersecting the column direction of the pixel) on the imaging substrate 101 has been described. The configuration of the fifth embodiment makes it difficult for the go-around magnetic field to interlink with the vertical signal line 130, and can suppress noise to the image signal.

### Sixth Embodiment

In the sixth embodiment, the orientation of a radiation magnetic field of the inductor will be described.

FIG. 12 is a layout diagram of the inductors 402a and 402b of the imaging substrate 101 in the sixth embodiment. In general, an inductor is configured by winding a conducting wire in a spiral shape, and the orientation of a magnetic field is determined by the orientation of a current flow by the right-hand screw rule. That is, the orientation of the magnetic field is determined by the orientation of winding the conducting wire.

Since the inductor 402a in FIG. 12 has a conducting wire wound anticlockwise (arrow orientation), an upward magnetic field is generated from the imaging substrate 101, but since the conducting wire of the inductor 402b is wound clockwise, the magnetic field is generated downward. The inductor 402a and the inductor 402b are close to each other, and due to a current flowing in the same orientation, magnetic fields are generated in opposite directions, and magnetic fields in opposite orientations interfere with each other. When magnetic fields in opposite orientations interfere with each other, they cancel each other out.

Therefore, in a case where a plurality of inductors are arranged on the imaging substrate 101, such as a case where the step-down switching power supply 400 includes a plurality of inductors or a case where a plurality of the step-down switching power supplies 400 are arranged on the imaging substrate 101, the inductors are arranged in orientations in which the magnetic fields cancel each other out. The magnetic field generated in the case where the plurality of step-down switching power supplies 400 are arranged can be suppressed. The arrangement of the inductors 402a and 402b in FIG. 12 is an example, and is not necessarily limited to this arrangement. A coupled inductor (type of inductor in which a plurality of inductors are enclosed in one inductor package) may be selected.

In the sixth embodiment, an example in which the plurality of inductors on the imaging substrate 101 are arranged in the orientation in which the magnetic fields cancel each other out has been described. The configuration of the sixth embodiment can suppress the magnetic field generated by the step-down switching power supply 400.

### Seventh Embodiment

In the seventh embodiment, the image sensor 102 of the stacked type will be described. The image sensor 102 includes a non-stacked type and a stacked type, and the stacked type has a characteristic of being less affected by a magnetic field than the non-stacked type. The image sensor 102 (see FIG. 2) includes the pixel unit 120a in which the plurality of pixels 110 are arranged in an array, and the circuit unit 170 in which a circuit responsible for control, signal processing, and the like is arranged.

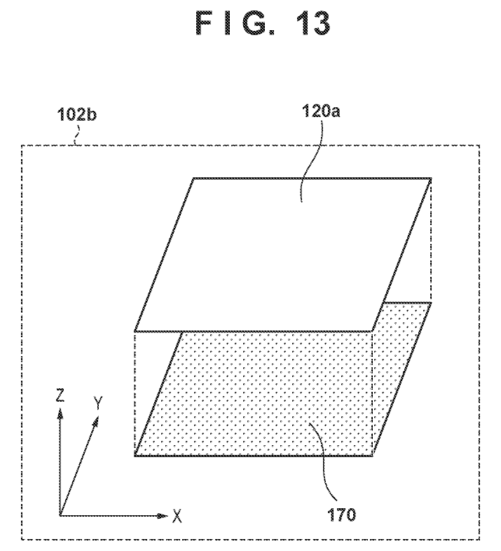

FIG. 13 is a view illustrating a schematic configuration of an image sensor 102b of the stacked type. The image sensor 102 of the non-stacked type (see FIG. 2) has a structure in which the pixel unit 120a and the circuit unit 170 are arranged on a plane (X-Y plane). On the other hand, the image sensor 102b of the stacked type has a structure in which a layer mounted with the pixel unit 120a and a layer mounted with the circuit unit 170 are stacked in the Z direction.

A mechanism in which noise is generated when the image capturing apparatus 300 receives a magnetic field will be described. When a closed loop including the vertical signal line 130 and a power supply wiring and a ground wiring not illustrated in the image capturing apparatus 300 receives a magnetic field, an induced electromotive force is generated in an orientation canceling the magnetic field. Next, an induced current in accordance with Ohm's law flows by the induced electromotive force and the resistance of the closed loop. Then, a voltage drop occurs due to the product of the induced current and the wiring resistance. Of the potential difference from this induced electromotive force due to the voltage drop, one generated in the pixel unit 120a is a noise voltage that causes image noise.

Here, attention is paid to wirings that affect image noise, such as the vertical signal line 130 in the pixel unit 120a, the power supply wiring, and the ground wiring. Since the non-stacked type has the pixel unit 120a and the circuit unit 170 mounted on a plane as described above, there is little available region for wiring inside the pixel unit 120a. On the other hand, in the stacked type, the pixel unit 120a and the circuit unit 170 are not on the same plane, and therefore, in a case where pixel unit areas of the image sensor 102 of the non-stacked type and the image sensor 102b of the stacked type are the same, the region available for wiring inside the pixel unit 120a is significantly wider in the stacked type than in the non-stacked type.

In general, the resistance is inversely proportional to the surface area and proportional to the length. Therefore, the stacked type that can secure a large wiring area in the pixel unit 120a reduces more the wiring resistance of the image sensor. Therefore, the voltage drop is small, the potential difference from the induced electromotive force is reduced, and noise is reduced. That is, by configuring the image sensor 102 as a stacked type, it is possible to reduce noise of the image signal.

In the seventh embodiment, an example in which the circuit unit and the pixel unit of the image sensor 102 have a stacked structure has been described. The configuration of the seventh embodiment can suppress noise of the image signal due to the magnetic field.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)^{TM}), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-172635, filed October 1, 2024, which is hereby incorporated by reference herein in its entirety.

WHAT IS CLAIMED IS:

1. An image capturing apparatus comprising:
a main substrate on which a power supply unit is arranged;
an image sensor including a pixel unit in which a plurality of pixels are two-dimensionally arranged, and a circuit unit that reads a signal of the pixels;
an imaging substrate mounted with the image sensor;
a flexible substrate that is connected to the main substrate and the imaging substrate and supplies power from the power supply unit to the imaging substrate; and
a step-down switching power supply that is mounted on a surface different from a surface on which the image sensor is mounted on the imaging substrate, steps down a voltage supplied via the flexible substrate, and supplies power to the image sensor, wherein
the step-down switching power supply includes an integrated circuit in which a switching element and a control circuit are integrated, a first capacitor connected to a power supply input side of the integrated circuit, an inductor connected to an output terminal of the integrated circuit, and a second capacitor connected to a terminal different from a terminal connected to an output terminal of the integrated circuit of the inductor, and
the inductor and the second capacitor are arranged, on the imaging substrate, outside a region where the image sensor is projected onto the imaging substrate.

2. The image capturing apparatus according to claim 1, wherein the integrated circuit and the first capacitor are arranged, on the imaging substrate, inside a region where the image sensor is projected onto the imaging substrate.

3. The image capturing apparatus according to claim 1, wherein the step-down switching power supply is arranged 1 mm or more away from an end of the imaging substrate.

4. The image capturing apparatus according to claim 1, wherein a switching frequency of the step-down switching power supply is higher than a readout frequency of the image sensor.

5. The image capturing apparatus according to claim 1, wherein the step-down switching power supply operates at a fixed switching frequency of 1 MHz or more.

6. The image capturing apparatus according to claim 1, wherein the step-down switching power supply operates at a switching frequency that varies depending on a load.

7. The image capturing apparatus according to claim 1, wherein a conductor is arranged at a position close to the step-down switching power supply at an end of the imaging substrate.

8. The image capturing apparatus according to claim 1, wherein the step-down switching power supply is covered with a conductor.

9. The image capturing apparatus according to claim 1, wherein in a case where the imaging substrate includes a plurality of inductors, the inductors are arranged in an orientation in which magnetic fields cancel each other out.

10. The image capturing apparatus according to claim 1, wherein the image sensor is an image sensor of a stacked type.

11. The image capturing apparatus according to claim 1, wherein the image sensor includes a signal line that is arranged in parallel to a column direction of a plurality of pixels arranged two-dimensionally and transfers a signal of the pixels, and the step-down switching power supply is arranged at a position close to an end of a side intersecting the column direction of the imaging substrate.

12. The image capturing apparatus according to claim 1, wherein the imaging substrate is a multilayer board, and a power supply line from the step-down switching power supply is wired in a layer away from the image sensor of the multilayer board.

13. The image capturing apparatus according to claim 1, wherein the power supply unit outputs a predetermined voltage higher than a voltage necessary for the image sensor to operate, and the predetermined voltage is supplied to the step-down switching power supply via the flexible substrate.
